(19) United States
(12) Patent Application Publication
(10) Pub. No.: US 2025/0372497 A1
(43) Pub. Date: Dec. 4, 2025

(54) SEMICONDUCTOR PACKAGES AND THE MANUFACTURING PROCESSES THEREOF

(71) Applicant: Taiwan Semiconductor Manufacturing Co., Ltd., Hsinchu (TW)

(72) Inventors: Chao-Wei Chiu, Hsinchu (TW); Hsuan-Ting Kuo, Taichung City (TW); Po-Ching Wu, Hsinchu (TW); Hsiu-Jen Lin, Zhubei City (TW); An-Jhih Su, Taoyuan City (TW)

(21) Appl. No.: 18/895,019

(22) Filed: Sep. 24, 2024

Related U.S. Application Data
(60) Provisional application No. 63/654,343, filed on May 31, 2024.

(51) Int. Cl. H01L 23/498; H01L 21/56; H01L 21/768; H01L 23/00; H01L 23/48; H01L 25/18; H10B 80/00

(52) U.S. Cl. CPC H01L 23/49838; H01L 21/56; H01L 21/76802; H01L 21/76877; H01L 21/76898; H01L 23/481; H01L 23/49833; H01L 24/16; H01L 24/32; H01L 24/73; H01L 25/18; H01L 2224/16225; H01L 2224/32225; H01L 2224/73204; H01L 2924/1436; H01L 2924/1815; H10B 80/00

(57) ABSTRACT

A method includes forming a composite package substrate, which includes forming through-openings in a dielectric core, filling the through-openings to form a first plurality of through-vias in the dielectric core, and forming a first interconnect structure and a second interconnect structure on opposing sides of the dielectric core. The first interconnect structure is connected to the second interconnect structure through the first plurality of through-vias. The method further includes bonding a local interconnect die to the first interconnect structure, forming a second plurality of through-vias directly from the first interconnect structure, encapsulating the second plurality of through-vias and the local interconnect die in an encapsulant, and forming a third interconnect structure over and electrically coupling to the local interconnect die and the second plurality of through-vias.

### PRIORITY CLAIM AND CROSS-REFERENCE

This application claims the benefit of the following provisionally filed U.S. patent application: Application No. 63/654,343, filed on May 31, 2024, and entitled “SEMICONDUCTOR PACKAGE AND MANUFACTURING PROCESSES THEREOF,” which application is hereby incorporated herein by reference.

### BACKGROUND

Interconnect dies have been used for electrically interconnecting device dies and packages, etc. Currently, the interconnect dies were embedded in Chip-on-wafer-on-substrate packages. The wafer in the package are often interposers.

With the increasingly demanding requirement of computing power, the interposers are being made increasingly larger. This posts problems because the overlay window is narrower when the interposers are larger. The problems such as cold joint are more likely to occur.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate the cross-sectional views of intermediate stages in the formation of a package including embedded interconnect dies in accordance with some embodiments.

FIGS. 11 and 12 illustrate the edges of a composite package substrate caused by sawing processes in accordance with some embodiments.

FIGS. 13-21 illustrate the cross-sectional views of intermediate stages in the formation of a composite package substrate having an embedded interconnect die in accordance with some embodiments.

FIGS. 22 and 23 illustrate the cross-sectional views of intermediate stages in the formation of a composite package substrate having an embedded interconnect die in accordance with some embodiments.

FIGS. 24 and 25 illustrate some interposers in accordance with some embodiments.

FIGS. 26 and 27 illustrate some chip-on-wafer chip-lets in accordance with some embodiments.

FIG. 28 schematically illustrates a chip-on-substrate package in accordance with some embodiments.

FIG. 29 schematically illustrates a chip-on-substrate package in accordance with some embodiments.

FIG. 30 schematically illustrates a chip-on-wafer-on-substrate package in accordance with some embodiments.

FIG. 31 schematically illustrates a top view of a chip-on-wafer-on-substrate package in accordance with some embodiments.

FIG. 32 schematically illustrates a cross-sectional view of a chip-on-substrate package in accordance with some embodiments.

FIG. 33 schematically illustrates a top view of a chip-on-substrate package in accordance with some embodiments.

FIG. 34 schematically illustrates a process flow of forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including an interconnect die, which may be a local silicon interconnect (LSI) die (also referred to as a bridge die) embedded in a package substrate and the method of forming the same are provided. In accordance with some embodiments of the present disclosure, a package substrate is formed. Through-vias may be formed through plating directly from the substrate. An LSI die is placed on the package substrate. The LSI die and the through-vias are then embedded in an encapsulant to form a composite package substrate. Package components (packages or device dies), which may or may not include interposers therein, are bonded to the composite package substrate, and are signally interconnected through the LSI die. By forming the LSI die in the composite package substrate, the package components may be made smaller, and when the chips include interposers therein, the interposers may also be made smaller. This reduces the overlay shift problem caused by the large interposers.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

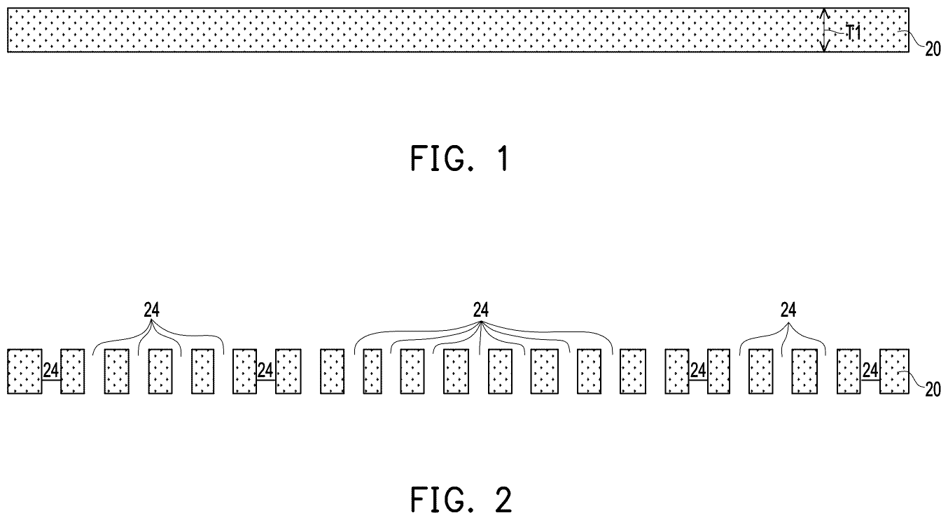

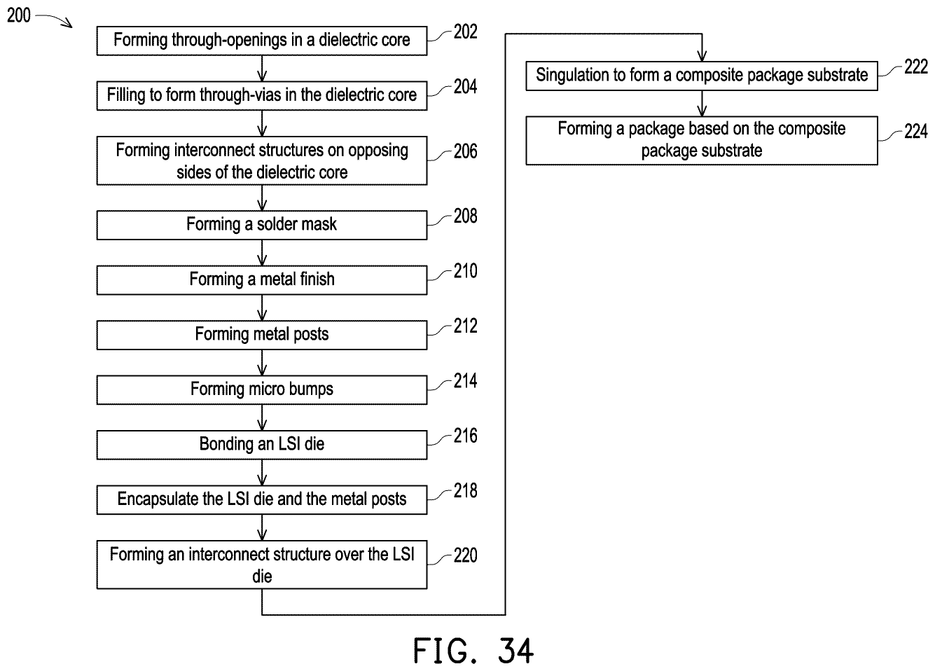

FIGS. 1-10 illustrate the cross-sectional views of intermediate stages in the formation of a package including embedded interconnect dies in accordance with some embodiments. The respective processes are illustrated in the process flow 200 as shown in FIG. 34.

Referring to FIG. 1, dielectric core 20 is provided. Dielectric core 20 may be formed of or comprises a homogeneous material such as a glass, which may comprise borosilicate, SiO2, sapphire, glassfiber core and/or the like. Dielectric core 20 may be free from other materials other than glass, which materials may include semiconductor materials, metallic materials, or the like. The width and length (such as diameter) of dielectric core 20 may be greater than, for example, 20 cm, 50 cm, or greater. The thickness T1 of dielectric core 20 may greater than about 800 μm.

Referring to FIG. 2, through-openings 24 may be formed, for example, through laser drilling, etching, or the like. The respective process is illustrated as process 202 in the process flow 200 as shown in FIG. 34. Through-openings 24 penetrate through dielectric core 20. The top-view shapes of through-openings 24 may include circles, rectangles, hexagons, octagons, or the like.

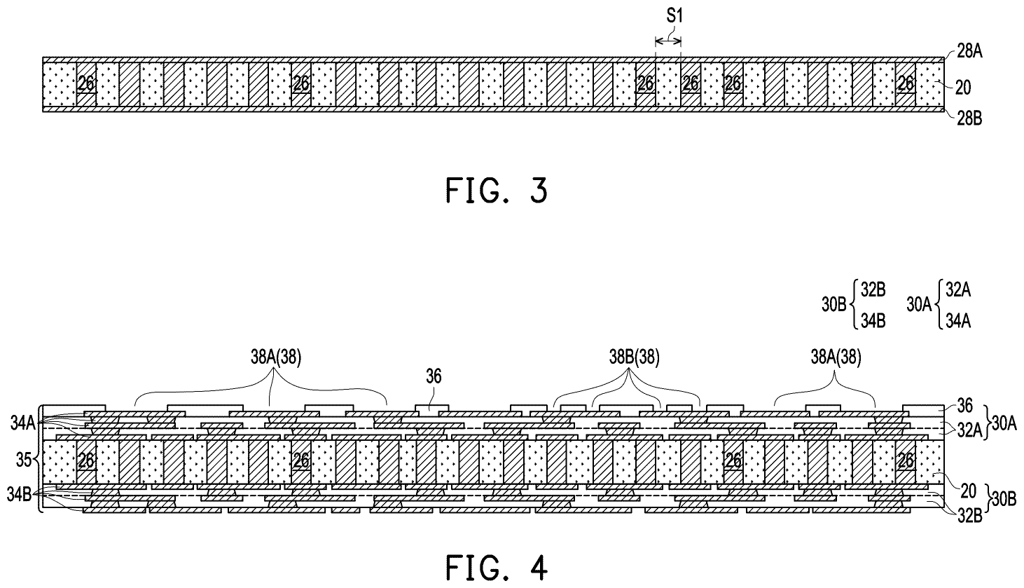

Next, referring to FIG. 3, through-openings 24 are filled with a conductive material through a plating process, forming through-vias 26 therein. The respective process is illustrated as process 204 in the process flow 200 as shown in FIG. 34. Conductive films 28A and 28B may also be formed on the front side and the backside of dielectric core 20, and may or may not be formed in the same plating process for forming through-vias 26. Through-vias 26 may be formed of a metallic material such as copper, tungsten, aluminum, titanium, nickel, or alloys thereof. In accordance with some embodiments, the spacings S1 between neighboring through-vias 26 may be in the range between about 50 μm and about 100 μm.

FIG. 4 illustrates the formation of interconnect structures 30A and 30B on the opposite sides of dielectric core 20. The respective process is illustrated as process 206 in the process flow 200 as shown in FIG. 34. The interconnect structure 30A may include dielectric layers 32A and redistribution lines (RDLs) 34A in dielectric layers 32A. The interconnect structure 30B may include dielectric layers 32B and redistribution lines (RDLs) 34B in dielectric layers 32B. The RDLs and the dielectric layers are also referred to as build-up layers. The RDLs 34A and 34B that are in contact with dielectric core 20 may be formed by patterning conductive films 28A and 28B, for example, through an etching process. The formation of the rest of the dielectric layer 32A and 32B and RDLs 34A and 34B may include forming and patterning dielectric layers, and plating the RDLs from the openings in the dielectric layers.

Dielectric layers 32A and 32B may be formed of or comprising Ajinomoto Build-up Film (ABF) films, which are laminated and patterned. Other dielectric materials such as polybenzoxazole (PBO), polyimide, benzocyclobutene (BCB), or the like may also be used. RDLs 34A and 34B may be formed of or comprising aluminum, copper, nickel, titanium, and/or the like. Since LSI die will be bonded in a subsequent process and used for signal re-routing, the front-side interconnect structure 30B (after the substrate is flipped upside-down as shown in FIG. 10) does not need to have many layers. The front-side interconnect structure 30B thus may have the same number of layers as, and is symmetrical to, the backside interconnect structure 30A. Accordingly, the stress applied on the dielectric core 20 is reduced.

Referring to FIG. 4, solder mask 36 is applied and patterned. The respective process is illustrated as process 208 in the process flow 200 as shown in FIG. 34. Solder mask 36 comprises a dielectric material, and is used to isolate and define the regions for the subsequently formed solder regions. Solder mask 36 may have openings 38 therein, which may include openings 38A for large solder regions (Ball Grid Arrays (BGAs)) and openings 38B, which are used for bonding device dies. The structure shown in FIG. 4 is referred to as package substrate 35 hereinafter.

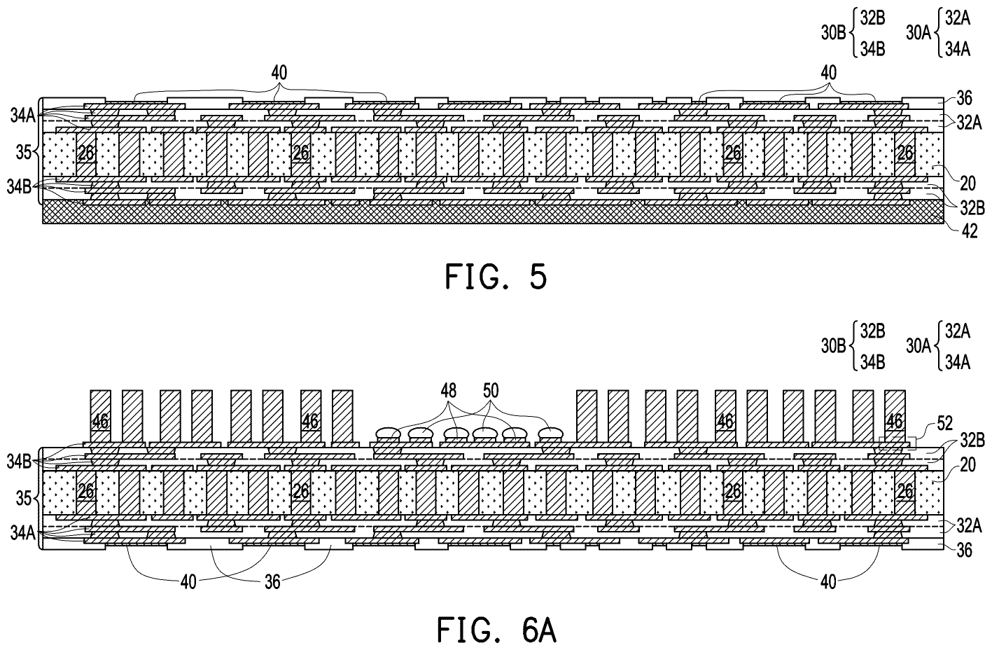

Referring to FIG. 5, a metal finish 40 may be formed on the exposed RDLs 34A, for example, through selective plating, to protect the exposed RDLs 34A from oxidation. The respective process is illustrated as process 210 in the process flow 200 as shown in FIG. 34. In accordance with some embodiments of the present disclosure, the metal finish 40 includes or comprises Electroless Nickel Electroless Palladium Immersion Gold (ENEPIG), Electroless Nickel Immersion Gold (ENIG), Direct Immersion Gold (DIG), or the like.

In accordance with some embodiments, protection film 42 is attached to RDLs 34B (or 34A), for example, through lamination. Protection film 42 may be formed of an organic material, and can be easily removed from the overlying structure. Protection film 42 may be used to prevent the damage of package substrate 35 if package substrate 35 is to be transmitted between manufacturing stations for subsequent processes. Otherwise, if the subsequent process is to be performed in a same manufacturing station as the preceding processes, protection film 42 may not be attached to package substrate 35.

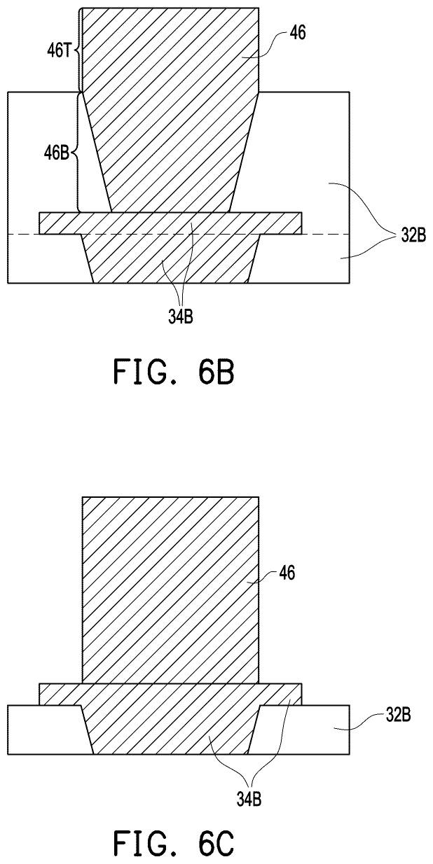

The protection film 42, if attached, will be removed after the structure formed in preceding process reaches next station. The resulting structure is shown in FIG. 6A, which shows an upside-down view than the structure shown in FIG. 5.

FIG. 6A further illustrates the formation of metal posts 46 directly from RDLs 34B in accordance with some embodiments. The respective process is illustrated as process 212 in the process flow 200 as shown in FIG. 34. In accordance with some embodiments, the formation process may include forming a metal seed layer (such as a copper layer, or a titanium layer and a copper layer over the titanium layer), forming and patterning a plating mask (not shown) such as a photoresist over the RDLs 34B, so that some portions of the metal seed layer directly over the RDLs 34B are exposed. A plating process is then performed to form metal posts 46, which may be formed of or comprise copper or a copper alloy. The plating mask is then removed, followed by an etching process to remove the portion of the metal seed layer previously covered by the plating mask.

In addition, micro bumps 48 and possibly solder layers 50 are also plated, which may be performed through similar processes as that of metal posts 46. The respective process is illustrated as process 214 in the process flow 200 as shown in FIG. 34. The micro bumps 48 may be formed before or after the formation of metal posts 46.

FIG. 6B illustrates an amplified view of region 52 in FIG. 6A in accordance with some embodiments. In FIG. 6B, the topmost layer is a dielectric layer 32B, which covers the topmost RDL 34B. In the formation of metal posts 46, the top dielectric layer 32 is first patterned, for example, through etching, laser drilling, or the like to expose the underlying RDL 34B. The metal seed layer and the plating mask may then be formed, followed by the plating process to form metal posts 46. The plating mask is then removed, and the metal seed layer is etched. In these embodiments, the bottom portions of metal posts 46 in the top dielectric layer 32B may have an abrupt change of sidewall profile when transitioning from portion 46T (higher than dielectric layer 32B) to the portion 46B (in dielectric layer 32B).

FIG. 6C illustrates an amplified view of region 52 in FIG. 6A in accordance with alternative embodiments. In FIG. 6C, the topmost layer is a metal pad portion of an RDL 34B. In the formation of metal posts 46, a metal seed layer and the plating mask are formed, followed by the plating process to form metal posts 46. The plating mask is then removed, and the metal seed layer is etched. The edges of metal posts 46 are thus straight and vertical.

In accordance with some embodiments, the interface between metal posts 46 and the underlying RDL 34B are distinguishable, for example, when the metal seed layer of metal posts 46 comprises titanium. In accordance with alternative embodiments, the interface between metal posts 46 and the underlying RDL 34B are not distinguishable, for example, when both the metal seed layer and the RDL 34B comprise copper, and the copper regions are in direct contact with each other.

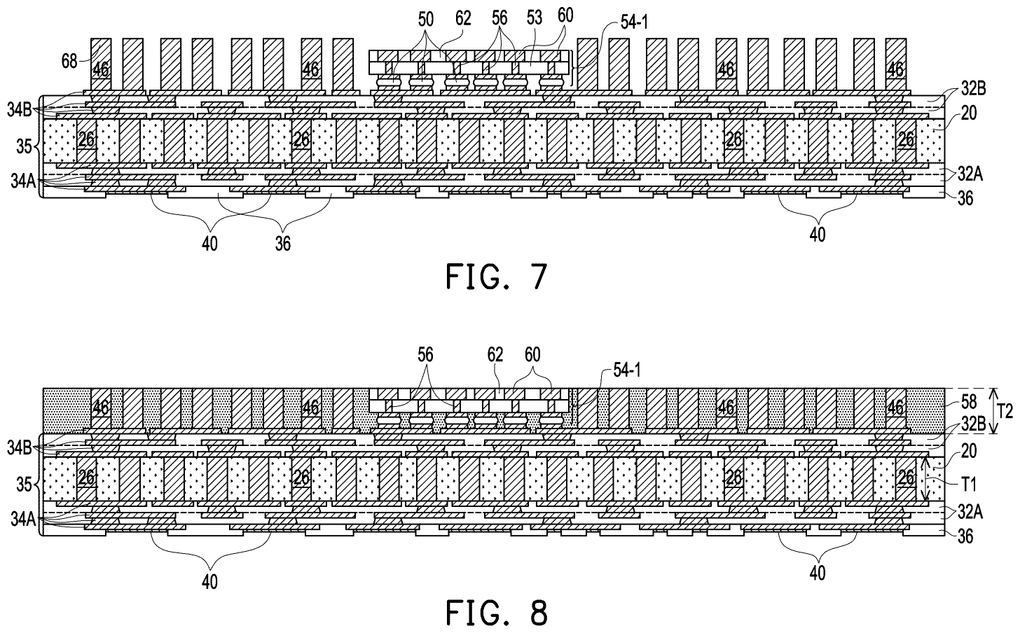

FIG. 7 illustrates the bonding of LSI die 54-1 (also referred to as a bridge die) in accordance with some embodiments, for example through solder regions 50. The respective process is illustrated as process 216 in the process flow 200 as shown in FIG. 34. LSI die 54-1 may include a semiconductor substrate 53 such as a silicon substrate. Through-vias 56 penetrate through the silicon substrate 53, and are used for connecting the features over LSI die 54-1 to the RDLs 34B.

Next, as shown in FIG. 8, encapsulant 58 is dispensed to encapsulate LSI die 54-1 and metal posts 46 therein. The respective process is illustrated as process 218 in the process flow 200 as shown in FIG. 34. Encapsulant 58 may include a molding compound, a molding underfill, an epoxy, and/or a resin, or other materials. The Young's modulus of encapsulant 58 may be in the range between about 10 Gpa and about 30 Gpa. The Coefficient of Thermal Expansion (CTE) of encapsulant of 58 may be greater than a first CTE (CTE1) and lower than a second CTE (CTE2). The CTE1 of layer 58 is in a range of 6˜14 ppm/K and the CTE2 of layer 58 is in a range of 20˜45. The CTE1 is the CTE of encapsulant 58 at the glass transition temperature of encapsulant 58. The CTE2 is the CTE of encapsulant 58 at a temperature higher than the glass transition temperature of dielectric core 20. When the encapsulation is finished, the top surface of encapsulant 58 is higher than the top ends of metal posts 46 and the top surfaces of LSI die 54-1.

Encapsulant 58 may include a base material, which may be a polymer, a resin, an epoxy, or the like, and filler particles in the base material. The filler particles may be dielectric particles formed of silica, alumina, boron nitride, or the like, and may have spherical shapes.

In accordance with some embodiments, dielectric core 20 may have thickness T1, which may be in the range between about 400 μm and about 1,000 μm. Encapsulant 58 may have thickness T2, which may be in the range between about 50 μm and about 100 μm. With thickness T2 being smaller than thickness T1, the stress introduced by encapsulant 58 may be reduced. The thickness ratio T1/T2 may be in the range between about 4 and about 20, for example.

A planarization process such as a Chemical Mechanical Polish (CMP) process or a mechanical grinding process is then performed to thin encapsulant 58 and LSI die 54-1, until metal posts 46 are revealed. Metal posts 46 are alternatively referred to as through-vias 46 hereinafter since they penetrate through encapsulant 58. In accordance with some embodiments in which LSI die 54-1 includes through-vias 56, which are connected to metal pads 60, metal pads 60 are also revealed by the planarization process. Metal pads 60 may be in dielectric layer 62, which may be PBO, polyimide, BCB, or the like.

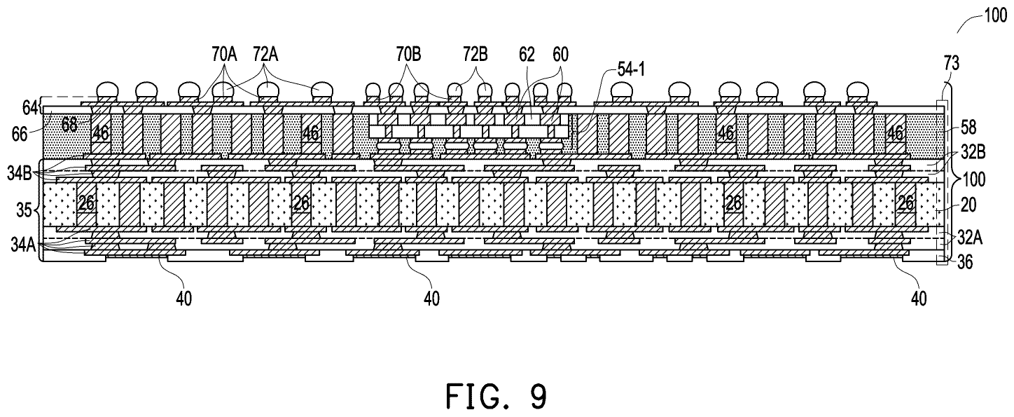

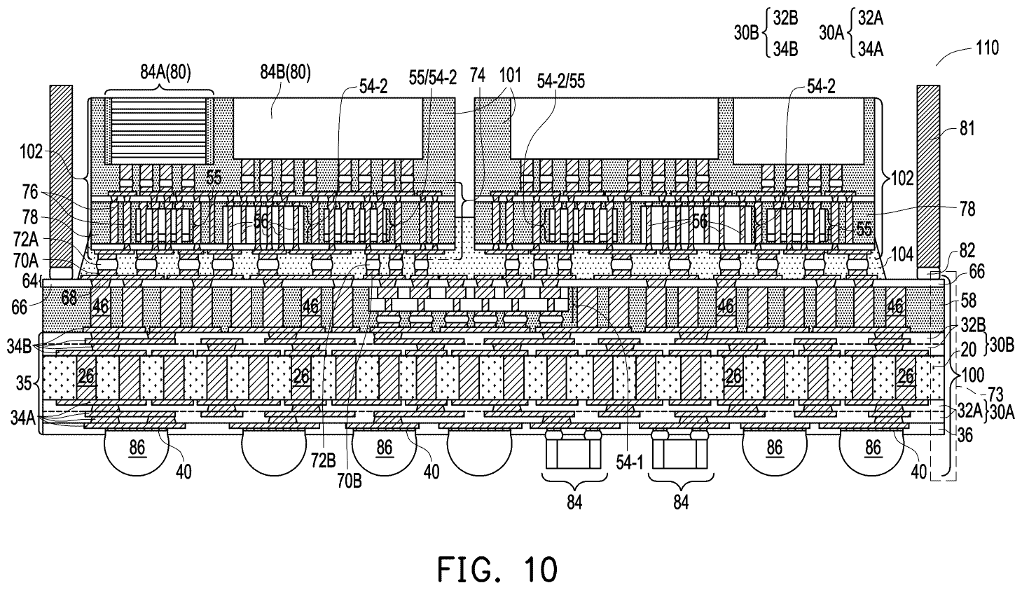

FIG. 9 illustrates the formation of redistribution structure 64 (also referred to as an interconnect structure), which may include dielectric layers 66 and RDLs 68. The respective process is illustrated as process 220 in the process flow 200 as shown in FIG. 34. Dielectric layers 66 may be formed of an organic material such as PBO, polyimide, or the like. Under-Bump Metallurgies (BUMs) 70A and solder regions 72A are formed. Micro-bumps 70B and solder regions 72B are also formed. A singulation process is then performed to saw the structure shown in FIG. 9 into one composite package substrate 100 through edge trimming, or into a plurality of identical composite package substrates 100. The respective process is illustrated as process 222 in the process flow 200 as shown in FIG. 34.

It is appreciated that composite package substrate 100 includes through-vias 46 formed directly from package substrate 35, LSI die 54-1 bonded directly to package substrate 35, and encapsulant 58 directly on package substrate 35.

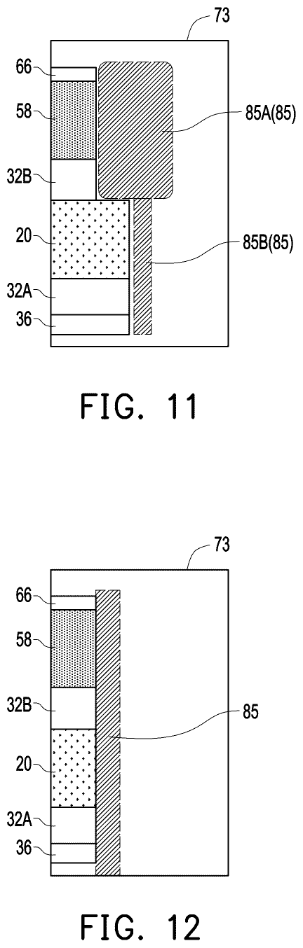

FIGS. 11 and 12 illustrate two example singulation processes to form composite package substrates 100. The illustrated region 73 is the edge region 73 in FIG. 9. FIG. 11 illustrates the singulation using two sawing blades 85A and 85B. Sawing blade 85A is a wide blade used to pre-groove the layers overlying dielectric core 20. Narrow blade 85B is then used to saw dielectric core 20 (and composite package substrates 100) apart. Through this sawing process, the edges of the upper portions of composite package substrate 100 is laterally recessed from the respective edges of dielectric core 20.

FIG. 12 illustrates the singulation using a single sawing blade 85. Through this sawing process, the edges of the upper portions of composite package substrate 100 are vertically aligned to the respective edges of dielectric core 20.

FIG. 10 illustrates the formation of a package 110 based on composite package substrate 100 (which may have been singulated or will be singulated in a subsequent process) in accordance with some embodiments. The respective process is illustrated as process 224 in the process flow 200 as shown in FIG. 34. Package components 102 (also referred to as packages) are bonded to composite package substrate 100, with underfill 104 being disposed in between.

In accordance with some embodiments as shown in FIG. 10, package 110 is a chip-on-wafer-on-substrate structure, wherein package components 80 (including package components 80A and 80B) are bonded to interposer 74. Interposers 74 may include encapsulants 78, which may be selected from the same candidate material of encapsulant 58. The bonding of package components 80 to interposer 74 may be performed with the interposers 74 being in an interposer wafer (hence the name chip-on-wafer). Encapsulants 101 may be used to encapsulate package components 80 therein. After package components 80 are bonded to interposers 74, the interposer wafer is sawed to form packages 102, which are referred to as chip-on-wafer packages. Packages 102 are then bonded to composite package substrate 100.

Package components 80A (also referred to as device dies when including device dies therein) may be High-bandwidth memory (HBM) stacks. Package components 80B may be device dies including discrete chips, System-on-Chip (SoC) dies, or the like. There may also be device dies 55 such as Deep Trench Capacitors (DTCs), Integrated Voltage Regulators (IVRs), active dies, independent passive devices (IPDs), or the like in encapsulant 78.

Furthermore, LSI dies 54-2 may be embedded in interposers 74 to electrically interconnect package components 80. LSI dies 54-2 may also be electrically connected to LSI dies 54-1. Accordingly, there may be LSI dies 54-2 for electrically and signally interconnecting the package components 80A and 80B in packages 102, and LSI dies 54-1 for electrically and signally interconnecting packages 102. Through this multi-layer distribution of LSI dies, the packages 102 may be made small, and the device dies may be made small. The warpage problems caused by large interposers are thus reduced or eliminated.

Package 110 may also include heat sink ring 81. A heat sink (not shown) may be over and joined to the heat sink ring 81. The heat sink ring 81 is attached to the underlying composite package substrate 100 through adhesive 82, and may be adhered to packages 102 through thermal interface materials. In addition, passive devices 84 may be bonded to the bottom of composite package substrate 100. Solder regions 86 may also be formed, and are electrically connected to the packages 102 through through-vias 26 and 46.

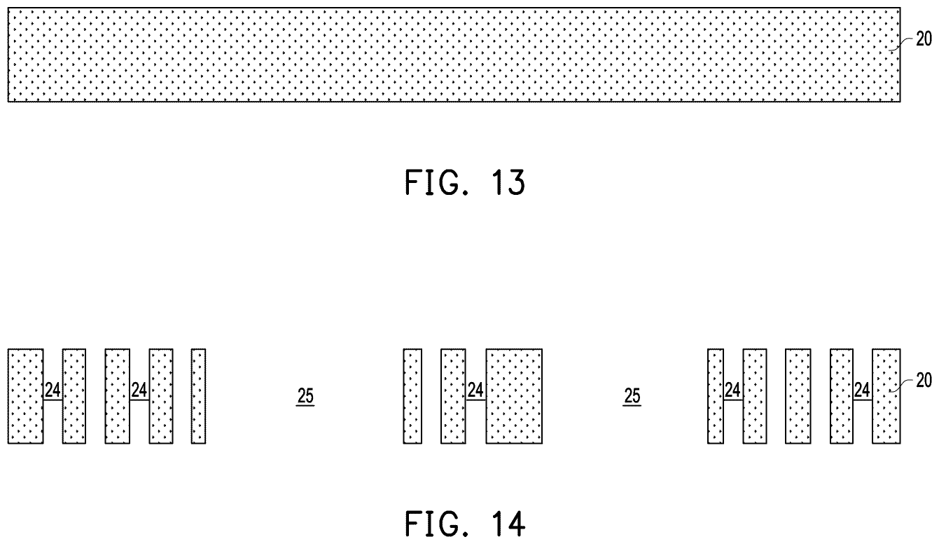

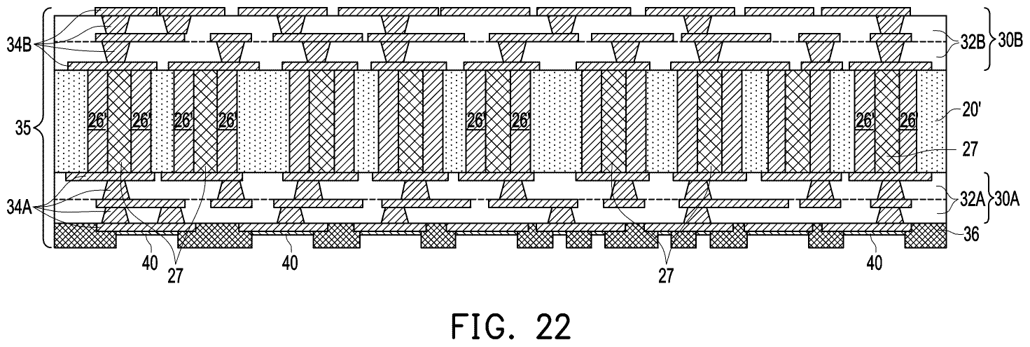

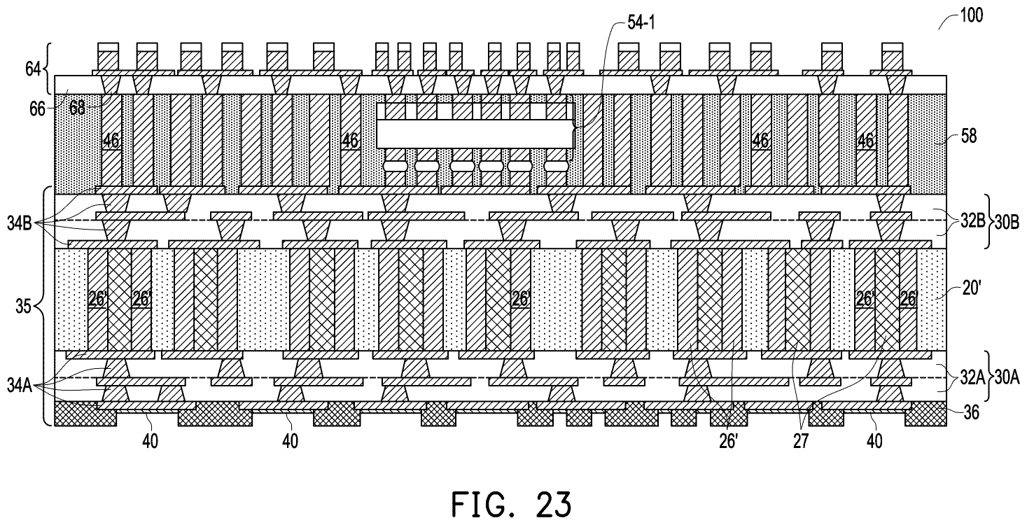

FIGS. 13 through 21 illustrate the formation of a composite package substrate 100 in accordance with alternative embodiments. These embodiments are essentially the same as the embodiments shown in FIGS. 1 through 10, except that some device dies are embedded in the dielectric core 20 also. Unless specified otherwise, the materials, the structures, and the formation processes of the components in these embodiments (and other subsequent embodiments including the processes as shown in FIGS. 22 and 23) are essentially the same as the like components denoted by like reference numerals in the preceding embodiments. The details regarding the materials, the structures, and the formation processes provided in each of the embodiments throughout the description may be applied to any other embodiment whenever applicable.

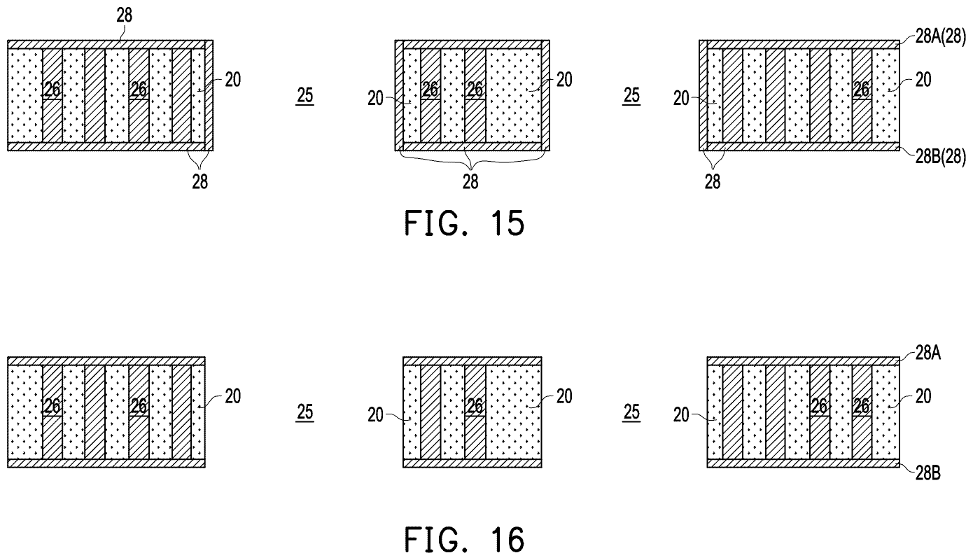

Referring to FIG. 13, dielectric core 20 is provided. Next, as shown in FIG. 14, through-openings 24 are formed. In addition, through-openings 25 are formed. The sizes of through-openings 25 are designed to hold device dies therein. Next, as shown in FIG. 15, through-openings 24 are filled (for example, through plating) with a conductive material to form through-vias 26. The conductive material is also formed on the sidewalls of dielectric core 20 and inside through-openings 25 for form conductive film 28, which also includes the conductive films 28A and 28B on the top side and the bottom side, respectively of dielectric core 20.

The portions of the conductive film 28 are then removed from through-openings 25, as shown in FIG. 16. In accordance with alternative embodiments, the portions of the conductive film 28 in through-openings 25 are not removed, and are used as the electrical shielding and/or thermal conductors.

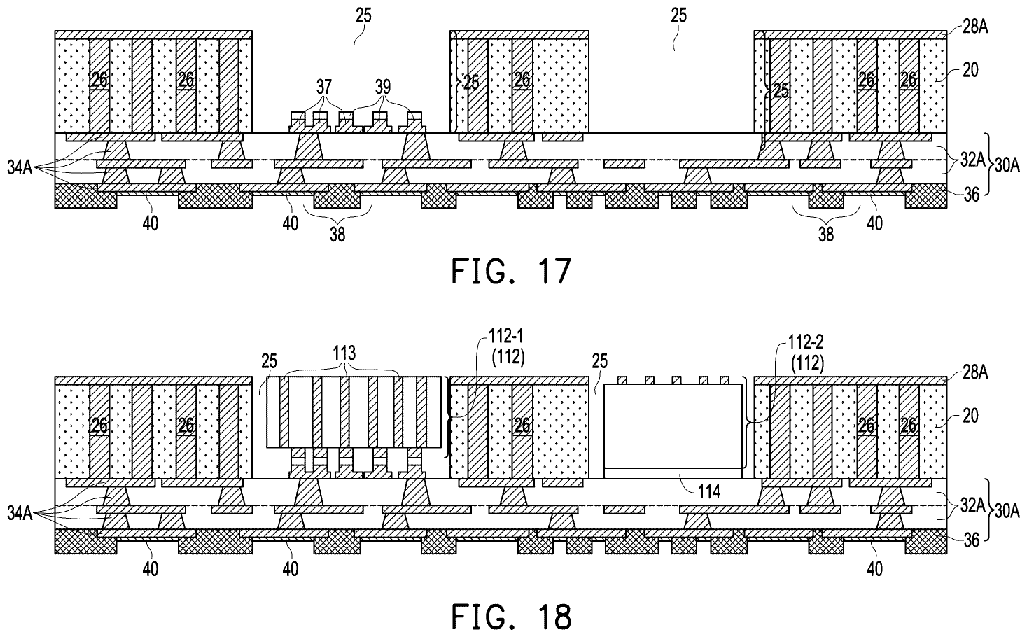

Referring to FIG. 17, interconnect structure 30A is formed, which includes dielectric layers 32A (formed of ABF or other dielectric materials as aforementioned in preceding embodiments) and RDLs 34A. Micro bumps 37, which may be copper bumps, are formed on RDLs 34A, with solder regions 39 being formed on micro bumps 37. Solder mask 36 is also formed to mask some edge portions of RDLs 34A, leaving openings 38 in solder mask 36. Metal finish 40 is then formed in openings 38 and on RDLs 34A.

Referring to FIG. 18, device dies 112 (including device dies 112-1 and 112-2) are disposed into through-openings 25. Device dies 112 are alternatively referred to as embedded package components. In accordance with some embodiments, device dies 112 may be selected from LSI dies, DTC dies, IVR dies, active device dies, passive device dies, or the like. In accordance with some embodiments, device die 112-1 is bonded to micro bumps 37 through solder regions 39. Device die 112-2, on the other hand, may have its backside attached to dielectric layer 32A, for example, through die-attach film 114. Device dies 112-1 may include through-vias 113, which penetrate through the semiconductor substrate in device dies 112.

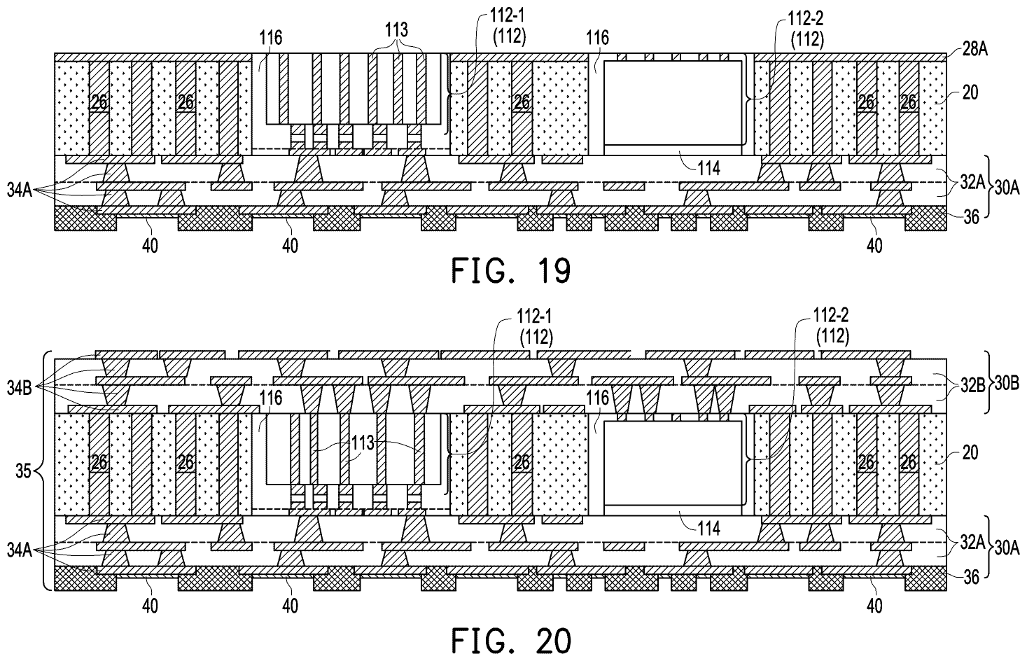

FIG. 19 illustrates the formation of dielectric regions 116 to encapsulate device dies 112. The formation process may include dispensing a dielectric material (which may be flowable) into the remaining openings 25, and curing the flowable dielectric material. The dielectric material may include an organic dielectric material such as epoxy underfill, a polymer (such as ABF), or the like. A planarization process is then performed to level the top surface of the dielectric material with conductive film 28A to form dielectric regions 116.

In subsequent processes, interconnect structure 30B is formed, which includes dielectric layers 32B and RDLs 34B. The layer of RDLs 34B in physical contact with dielectric core 20 may be formed by patterning (through etching) conductive film 28A. The remaining portions of the RDLs 34B may be formed through plating. RDLs 34B are electrically connected to device dies 112, and may also be electrically connected to RDLs 34A through through-vias 26 and the through-vias 113 in device die 112.

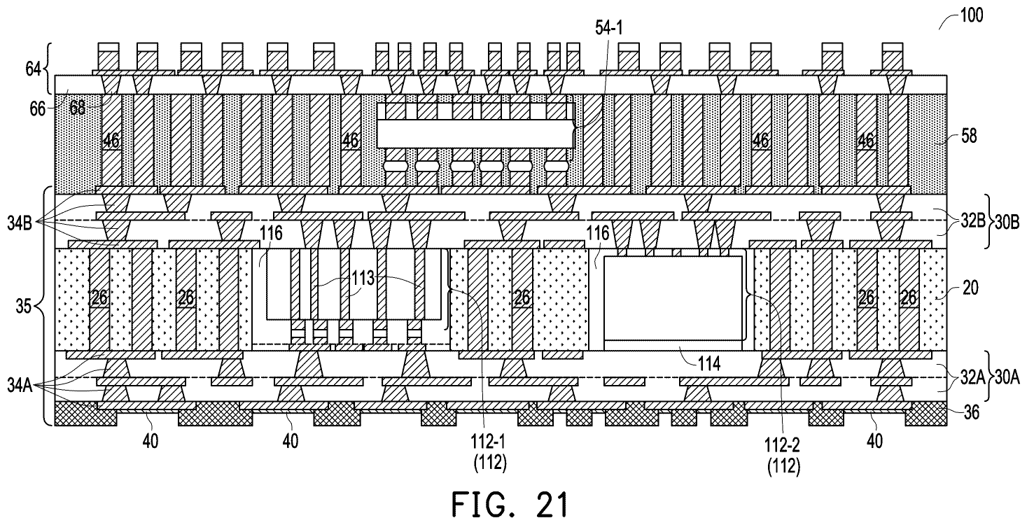

Referring to FIG. 21, through-vias 46 are formed, and LSI die 54-1 is bonded. The through-vias 46 and LSI die 54-1 are encapsulated in encapsulant 58. The details of these processes may be found in the description of FIGS. 6A, 6B, 6C and 7-9, and are not repeated herein. Composite package substrate(s) 100 are thus formed.

A singulation process, as shown in FIGS. 11 and 12 may then be performed through an edge-trimming process to form a single composite package substrate 100, or to form a plurality of composite package substrate(s) 100. The resulting composite package substrate 100 is shown in FIG. 21. In a subsequent process, more package components may be bonded to form a package (not shown) similar to the package 110 as shown in FIG. 10. The processes and structures are essentially the same as that in FIG. 10, except the structure of composite package substrate 100 in FIG. 10 is changed to the composite package substrate 100 in FIG. 21.

FIGS. 22 and 23 illustrate the views of intermediate stages in the formation of a composite package substrate 100 in accordance with yet alternative embodiments. These embodiments are similar to the embodiments as shown in FIGS. 1 through 10, except that the dielectric core (denoted as 20′) is formed of an organic material, rather than the inorganic material such as glass. In addition, the through-vias 26 have been replaced with Plated Through Holes (PTHs) 26′.

Referring to FIG. 22, package substrate 35 is formed. In accordance with some embodiments, the PTHs 26′ may be formed of or comprise copper, nickel, aluminum, or the like, and are formed as conductive pipes. In accordance with some embodiments, the formation processes are essentially the same as what are shown in FIGS. 13-17, except the through-openings 25 as shown in FIG. 15 are narrow openings, for example, with circular top view shapes. The narrow through-openings may then be filled with a dielectric layer to form dielectric filling regions 27 as shown in FIG. 22. Interconnect structure 30A as shown in FIG. 22 may then be formed.

In accordance with some embodiments, the dielectric core 20′ may be formed of or comprise an organic material such as glass fiber, prepreg (which comprises epoxy, resin, and/or glass fiber), resin coated Copper (RCC), glass, plastic (such as PolyVinylChloride (PVC), Acrylonitril, Butadiene & Styrene (ABS), Polypropylene (PP), Polyethylene (PE), PolyStyrene (PS), Polymethyl Methacrylate (PMMA), Polyethylene Terephthalate (PET), Polycarbonates (PC), Polyphenylene sulfide (PPS), flex (polyimide), molding compound, a molding underfill, an epoxy, resin, or combinations thereof. The dielectric filling regions 118 may be formed or comprise a material selected from the above recited materials.

Interconnect structure 30B is then formed on the opposite side of the dielectric core 20′ and the PTHs 26′ than interconnect structure 30A. The RDLs 34A are electrically connected to the RDLs 34B though PTHs 26′.

Next, as shown in FIG. 23, LSI die 54-1 is bonded to the micro bumps formed on RDLs 34B. Through-vias 46 are also formed, followed by encapsulating (such as molding) LSI die 54-1 and through-vias 46 in encapsulant 58. Interconnect structure 64 is then formed. A singulation process may then be performed through trimming or sawing (as shown in FIGS. 11 and 12) to form composite package substrates 100, as shown in FIG. 23.

In a subsequent process, more package components may be bonded to form a package (not shown) similar to the package 110 as shown in FIG. 10. The processes and structures are essentially the same as that in FIG. 10, except the structure of composite package substrate 100 in FIG. 10 is changed to the composite package substrate 100 in FIG. 23.

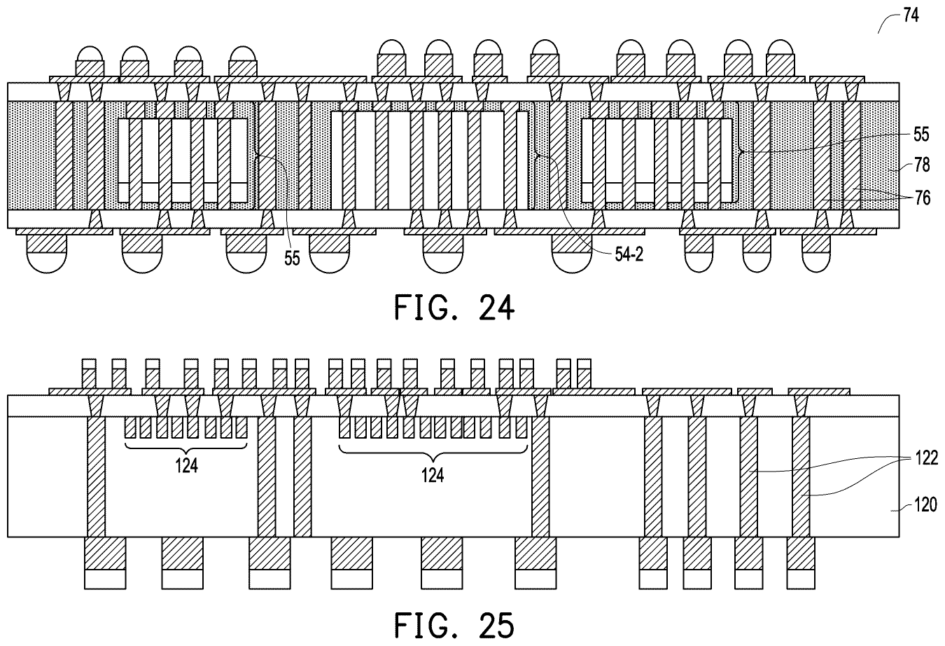

Some package components in the packages of the embodiments are illustrated and discussed briefly hereinafter. FIGS. 24 and 25 illustrate two candidate interposers 74 in accordance with some embodiments. The interposers 74 may be adopted in the package 110 as shown in FIG. 10, in which the interposers 74 are bonded with package component 80 to form packages 102, which packages 102 are further bonded to composite package substrate 100.

FIG. 24 illustrates an interposer 74 same as the interposer 74 as shown in FIG. 10. The details are thus not repeated herein. The interposer 74 is based on an LSI die. The interposer 74 is a package that includes LSI die 54-2 for bridging the overlying package components, and may or may not include device dies 55.

FIG. 25 illustrates a semiconductor-based (such as silicon-based) interposer 74, which includes semiconductor substrate 120 (such as a silicon substrate). Through-vias 122 are formed to penetrate through the semiconductor substrate 120. In accordance with some embodiments, the interposer 74 may include passive devices 124, which may be, for example, capacitors, inductors, resistors, and/or the like. For example, the passive devices 124 may include DTCs formed in semiconductor substrate 120.

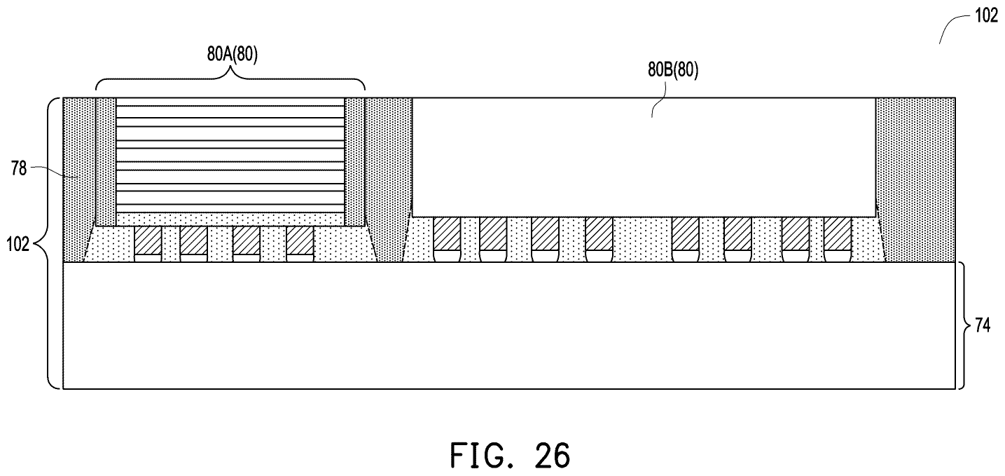

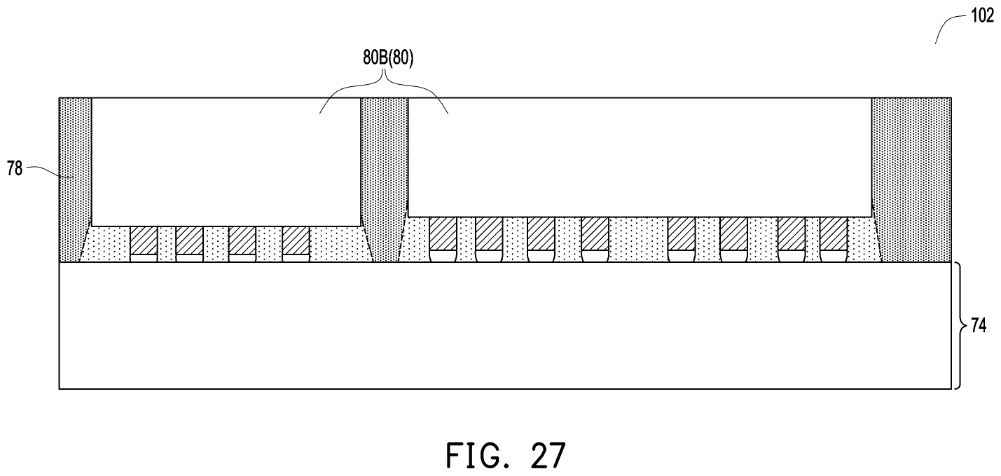

FIGS. 26 and 27 illustrate example packages 102 (which may be CoW chip-lets) in accordance with some embodiments. In FIG. 26, HBM 80A and device die 80B are bonded to interposer 74 to form the package 102. In FIG. 27, a plurality of device dies 80B are bonded to interposer 74 to form the package 102. The interposers 74 as shown in FIGS. 26 and 27 may adopt any structure including the structures shown in FIGS. 24 and 25.

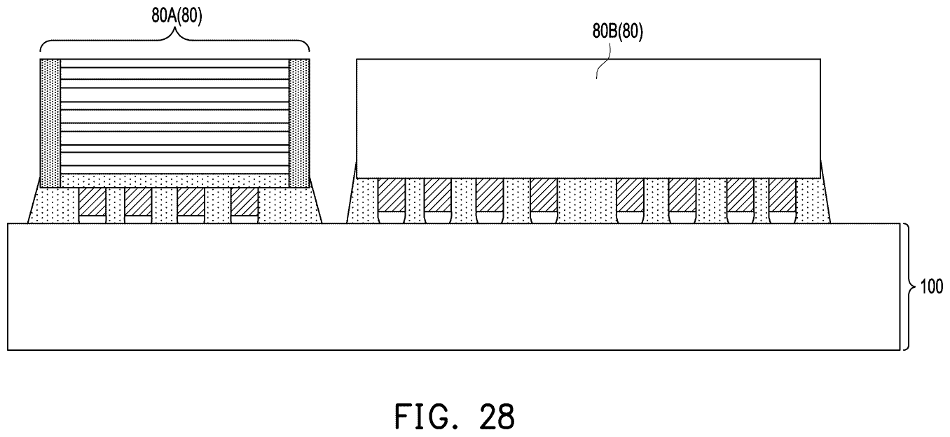

In the structure shown in FIGS. 26 and 27, device dies are bonded to interposers 74, which are further bonded to the composite package substrate 100 (as shown in FIG. 10 and the subsequently shown FIG. 3). FIG. 28 illustrates an alternative embodiment, in which device dies 80 are bonded to the composite package substrate 100 directly, without interposers in between. The composite package substrate 100 may adopt any of the structures shown in FIGS. 10, 21, and 23.

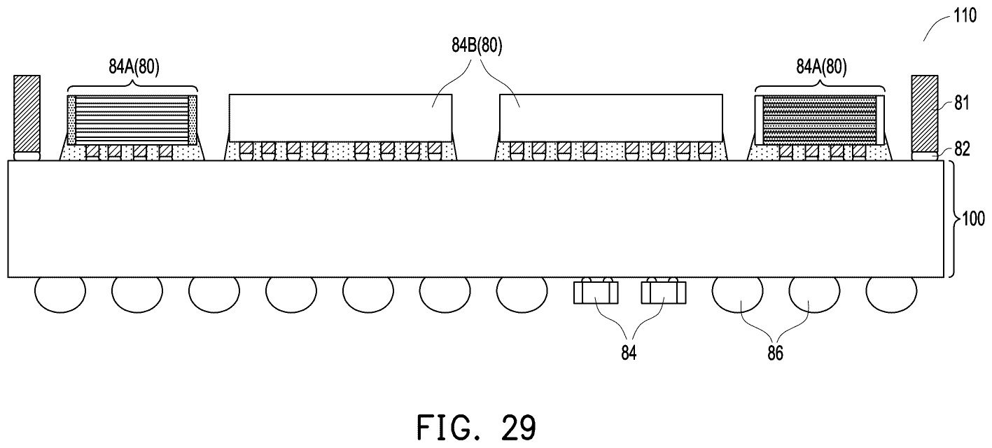

FIG. 29 illustrates an embodiment similar to the embodiment as shown in FIG. 28, except more components are illustrated. For example, heat sink ring 81 may be attached to the front side of the composite package substrate 100 through adhesive 82, and package components 80 are attached to the backside of the composite package substrate 100.

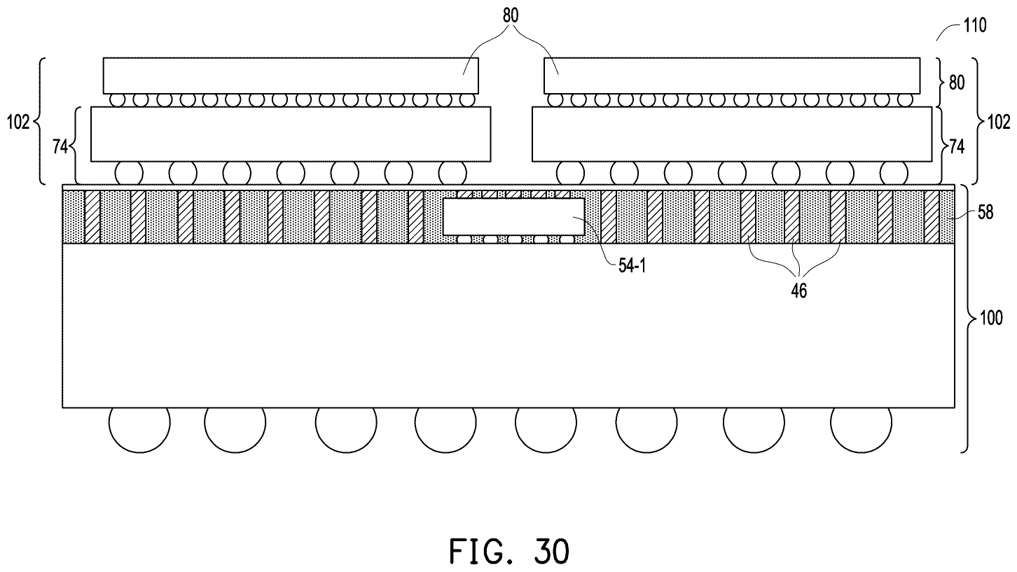

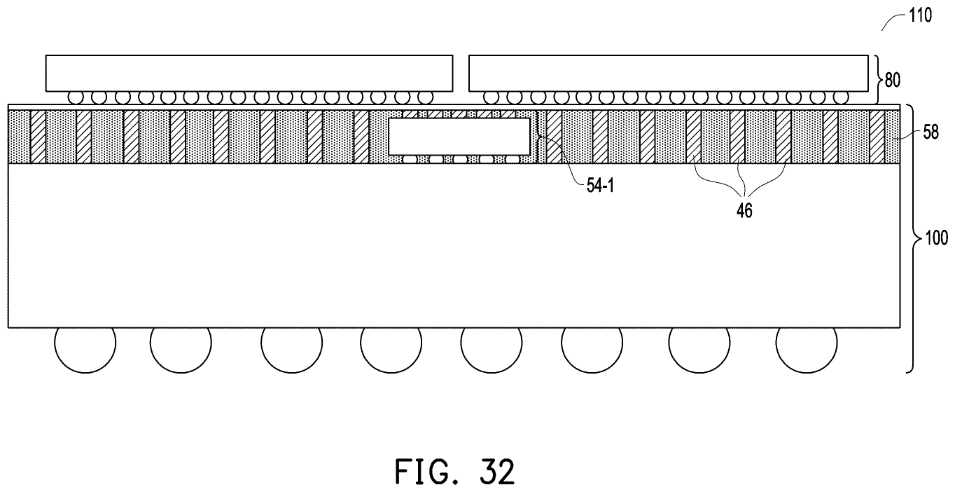

FIGS. 30 and 32 illustrate the schematic view of the packages with or without interposers 74 over the composite package substrate 100 in accordance with some embodiments. FIGS. 30 and 32 schematically illustrate some package components as blocks, and the details of these package components may be found from the precedingly illustrated Figures.

Referring to FIG. 30, the composite package substrate 100 (referring to FIGS. 10, 21, and 23 for details) have packages 102 bonded thereon. Packages 102 may include interposers 74 and package components 80 bonded thereon. Accordingly, the package 110 as shown in FIG. 30 includes interposers 74 between the composite package substrate 100 and package components 80 (including device dies).

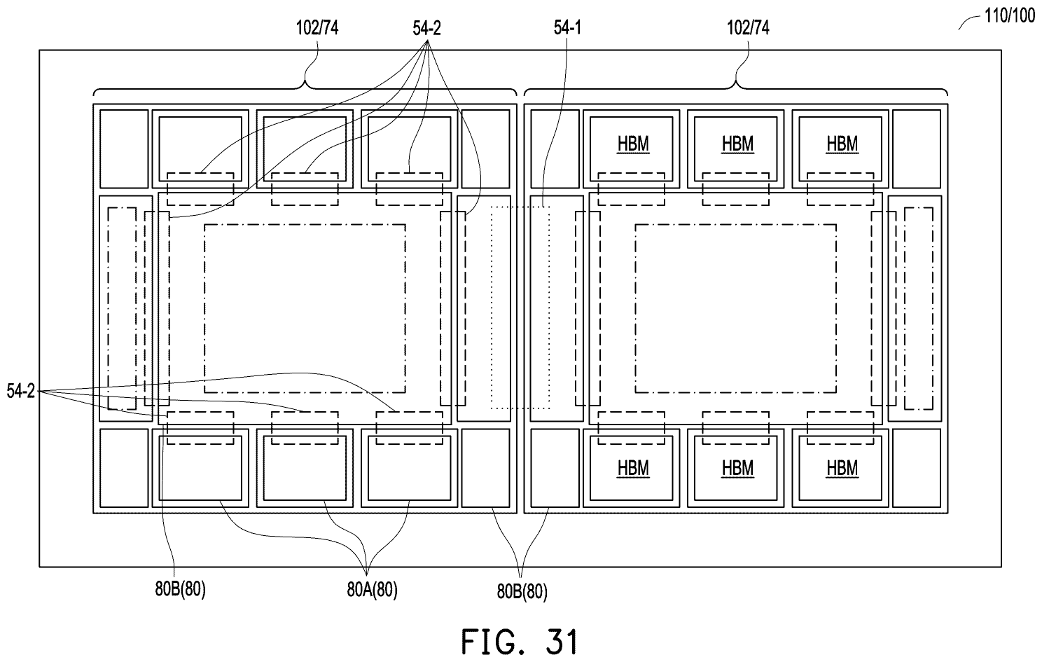

FIG. 31 illustrates a top view of the package 110 shown in FIG. 31, in which packages 102 (CoW chip-lets) are incorporated. There are two packages 102, which are electrically and signally inter-coupled through LSI die 54-1, which is in the underlying composite package substrate 100. A plurality of package components (HBMs) 80A and a plurality of package components (device dies) 80B are illustrated, which are electrically and signally inter-coupled through LSI dies 54-2 that are in interposers 74.

Referring to FIG. 32, the composite package substrate 100 (referring to FIGS. 10, 21, and 23 for details) have package components (such as device dies or HBMs) 80 directly bonded thereon. Accordingly, the package 110 as shown in FIG. 32 is free from interposers between the composite package substrate 100 and package components 80.

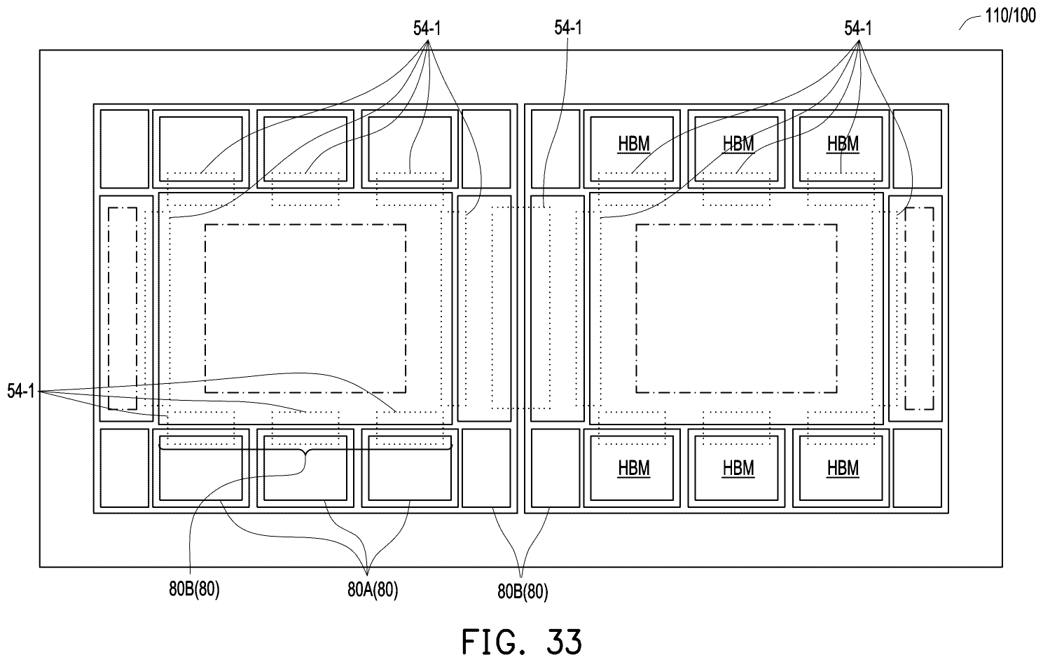

FIG. 33 illustrates a top view of the package 110 shown in FIG. 32, in which package components 80 are directly bonded to the composite package substrate 100 without interposers in between. Since there is not interposer (and hence no LSI die 54-2), all LSI dies are the LSI dies 54-1 that are in composite package substrate 100.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming large composite package substrates including LSI dies embedded therein, interposers (if any) can be made smaller. The composite package substrates have higher tolerance to overlay shift than the interposers. Accordingly, forming large composite package substrates is less likely to have overlay shift than forming large interposers. Furthermore, by adopting glass dielectric core, the through-vias in the composite package substrate may have a higher density than in an organic core. Since LSI dies may be distributed to the composite package substrate and the interposers, the reticle size of the lithography process in the formation of the components in the package may be reduced, leading to the reduction of likely problems.

In accordance with some embodiments of the present disclosure, a method comprises forming a composite package substrate comprising forming through-openings in a dielectric core; filling the through-openings to form a first plurality of through-vias in the dielectric core; forming a first interconnect structure and a second interconnect structure on opposing sides of the dielectric core, wherein the first interconnect structure is connected to the second interconnect structure through the first plurality of through-vias; bonding a first local interconnect die to the first interconnect structure; forming a second plurality of through-vias directly from the first interconnect structure; encapsulating the second plurality of through-vias and the first local interconnect die in an encapsulant; and forming a third interconnect structure over and electrically coupling to the first local interconnect die and the second plurality of through-vias.

In an embodiment, the forming the second plurality of through-vias comprises plating the second plurality of through-vias directly from the first interconnect structure. In an embodiment, the first local interconnect die further comprises a third plurality of through-vias therein, wherein the third plurality of through-vias electrically connect the third interconnect structure to the first interconnect structure. In an embodiment, the dielectric core comprises a glass core. In an embodiment, the dielectric core comprises an organic dielectric material.

In an embodiment, the method further comprises forming a first additional opening in the dielectric core; and embedding a second local interconnect die in the first additional opening, wherein the first interconnect structure is connected to the second interconnect structure through additional through-vias in the second local interconnect die. In an embodiment, the method further comprises forming a second additional opening in the dielectric core; and embedding a passive device die in the second additional opening.

In an embodiment, the method further comprises bonding a first package and a second package to the composite package substrate, wherein the first local interconnect die electrically connect the first package to the second package. In an embodiment, the first package comprises an interposer; and a first device die and a second device die over and bonding to the interposer.

In an embodiment, the interposer further comprises a second local interconnect die, wherein the first device die is signally connected to the second device die through the second local interconnect die. In an embodiment, the method further comprises bonding a first device die and a second device die to the composite package substrate, wherein the first local interconnect die electrically connect the first device die to the second device die. In an embodiment, the method further comprises sawing the composite package substrate from a respective wafer.

In accordance with some embodiments of the present disclosure, a structure comprises a package substrate comprising a dielectric core; a first plurality of through-vias in the dielectric core; a first interconnect structure comprising a first plurality of redistribution lines overlying and electrically connected to the first plurality of through-vias; and a second interconnect structure comprising a second plurality of redistribution lines underlying and electrically connected to the first plurality of through-vias; a first bridge die over and joined to the first interconnect structure; and an encapsulant over and contacting the first interconnect structure, wherein the first bridge die is in the encapsulant, and wherein the package substrate, the first bridge die, and the encapsulant collectively form a composite package substrate.

In an embodiment, the first bridge die comprises a second plurality of through-vias therein, and wherein the second plurality of through-vias are electrically connected to the first plurality of through-vias. In an embodiment, the structure further comprises a first package and a second package over and joined to the composite package substrate, wherein the first package is signally connected to the second package through the first bridge die. In an embodiment, the first package comprises an interposer; and a first device die and a second device die over and joined to the interposer. In an embodiment, the interposer further comprises a second bridge die, and wherein the first device die is signally connected to the second device die through the second bridge die.

In accordance with some embodiments of the present disclosure, a structure comprises a composite package substrate comprising a first interconnect structure; a first local interconnect die over and electrically coupling to the first interconnect structure; and a second interconnect structure over and electrically coupling to the first interconnect structure and the first local interconnect die; and an interposer over and electrically coupling to the composite package substrate, wherein the interposer is signally coupled to the first local interconnect die, and wherein the interposer further comprises a second local interconnect die; and a first package component and a second package component over the second local interconnect die, wherein the first package component is signally coupled to the second package component through the second local interconnect die.

In an embodiment, the first local interconnect die comprises a first semiconductor substrate; and a first plurality of through-vias in the first semiconductor substrate. In an embodiment, the second local interconnect die comprises a second semiconductor substrate; and a second plurality of through-vias in the second semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a composite package substrate comprising:
forming through-openings in a dielectric core;
filling the through-openings to form a first plurality of through-vias in the dielectric core;
forming a first interconnect structure and a second interconnect structure on opposing sides of the dielectric core, wherein the first interconnect structure is connected to the second interconnect structure through the first plurality of through-vias;
bonding a first local interconnect die to the first interconnect structure;
forming a second plurality of through-vias directly from the first interconnect structure;
encapsulating the second plurality of through-vias and the first local interconnect die in an encapsulant; and
forming a third interconnect structure over and electrically coupling to the first local interconnect die and the second plurality of through-vias.

2. The method of claim 1, wherein the forming the second plurality of through-vias comprises plating the second plurality of through-vias directly from the first interconnect structure.

3. The method of claim 1, wherein the first local interconnect die further comprises a third plurality of through-vias therein, wherein the third plurality of through-vias electrically connect the third interconnect structure to the first interconnect structure.

4. The method of claim 1, wherein the dielectric core comprises a glass core.

5. The method of claim 1, wherein the dielectric core comprises an organic dielectric material.

6. The method of claim 1, further comprising:
forming a first additional opening in the dielectric core; and
embedding a second local interconnect die in the first additional opening, wherein the first interconnect structure is connected to the second interconnect structure through additional through-vias in the second local interconnect die.

7. The method of claim 1, further comprising:
forming a second additional opening in the dielectric core; and
embedding a passive device die in the second additional opening.

8. The method of claim 1, further comprising bonding a first package and a second package to the composite package substrate, wherein the first local interconnect die electrically connect the first package to the second package.

9. The method of claim 8, wherein the first package comprises:
an interposer; and
a first device die and a second device die over and bonding to the interposer.

10. The method of claim 9, wherein the interposer further comprises a second local interconnect die, wherein the first device die is signally connected to the second device die through the second local interconnect die.

11. The method of claim 1, further comprising bonding a first device die and a second device die to the composite package substrate, wherein the first local interconnect die electrically connect the first device die to the second device die.

12. The method of claim 1, further comprising sawing the composite package substrate from a respective wafer.

13. A structure comprising:
a package substrate comprising:
a dielectric core;
a first plurality of through-vias in the dielectric core;
a first interconnect structure comprising a first plurality of redistribution lines overlying and electrically connected to the first plurality of through-vias; and
a second interconnect structure comprising a second plurality of redistribution lines underlying and electrically connected to the first plurality of through-vias;
a first die over and joined to the first interconnect structure; and
an encapsulant over and contacting the first interconnect structure, wherein the first die is in the encapsulant.

14. The structure of claim 13, wherein the first die comprises a second plurality of through-vias therein, and wherein the second plurality of through-vias are electrically connected to the first plurality of through-vias.

15. The structure of claim 13, further comprising:
a first package and a second package over and joined to the package substrate, wherein the first package is signally connected to the second package through the first die.

16. The structure of claim 15, wherein the first package comprises:
an interposer; and
a first device die and a second device die over and joined to the interposer.

17. The structure of claim 16, wherein the interposer further comprises a second die, and wherein the first device die is signally connected to the second device die through the second die.

18. A structure comprising:
a package substrate comprising:
a first interconnect structure;
a first die over and electrically coupling to the first interconnect structure; and
a second interconnect structure over and electrically coupling to the first interconnect structure and the first die; and
an interposer over and electrically coupling to the package substrate, wherein the interposer is signally coupled to the first die, and wherein the interposer further comprises:
a second die.

19. The structure of claim 18, wherein the first interconnect structure comprises:
a first semiconductor substrate; and
a first plurality of through-vias in the first semiconductor substrate.

20. The structure of claim 18, wherein the interposer further comprises a first package component and a second package component over the second interconnect structure, wherein the first package component is signally coupled to the second package component through the second interconnect structure.
